(19) United States
(12) Patent Application Publication
(10) Pub. No.: US 2024/0145242 A1
(43) Pub. Date: May 2, 2024

(54) METHOD OF BLOCKING DIELECTRIC SURFACES USING BLOCKING MOLECULES TO ENABLE SELECTIVE EPI DEPOSITION

(71) Applicant: Applied Materials, Inc., Santa Clara, CA (US)

(72) Inventors: Geetika BAJAJ, Cupertino, CA (US); Srobona SEN, Mumbai (IN); Xuebin LI, Sunnyvale, CA (US); Joe MARGETIS, Gilbert, AZ (US); Provas PAL, West Bengal (IN); Gopi Chandran RAMACHANDRAN, Mumbai (IN)

(21) Appl. No.: 18/384,688

(22) Filed: Oct. 27, 2023

(30) Foreign Application Priority Data
Oct. 28, 2022 (IN) 202241061456

(51) Int. Cl. H01L 21/02; H01L 21/3205

(52) U.S. Cl. CPC H01L 21/02642; H01L 21/02052; H01L 21/02532; H01L 21/32055

(57) ABSTRACT

Implementations described herein generally relate to processes for the fabrication of semiconductor devices in which a blocking layer of molecules is used to achieve selective epitaxial deposition. In one implementation, a method of processing a mixed-surface substrate comprising an exposed dielectric material and an exposed silicon-based material is provided. The method comprises depositing a blocking layer on the exposed dielectric material and epitaxially and selectively depositing a silicon-containing material layer on the exposed silicon-based material at a temperature of 400 degrees Celsius or greater. The method further involves removing the blocking layer from the dielectric material.

### CROSS-REFERENCE TO RELATED APPLICATIONS

This application claims priority to Indian Provisional Patent Application Serial No. 202241061456, filed on Oct. 28, 2022, which is herein incorporated by reference in its entirety.

### BACKGROUND

### Field

Embodiments of the present disclosure generally relate to processes for the fabrication of semiconductor devices in which a blocking layer of blocking molecules is used to achieve selective epitaxial deposition.

### Description of the Related Art

A technological progression that is common to modern-day electronics is miniaturization. As electronics technologies evolve and advance, transistors and interconnects become smaller and smaller. This miniaturization allows for the manufacture of semiconductor silicon wafers with higher circuit densities. Circuit miniaturization has also led to lateral improvements, including decreases in cost and power consumption and increases in speed. In order to continue transistor miniaturization, and to deliver higher performance, lower power consumption devices, new architectures and manufacturing techniques will need to be developed.

One miniaturization technique for reducing semiconductor surface area involves adding vertical layers. Each layer must be highly uniform, extremely smooth, and have good adhesion to an adjacent layer. Manufacturing techniques for stacked electronics become more challenging as the number of layers is increased, and increasing the number of layers presents greater complexities during subsequent processing steps. Stacking multiple layers often involves selective epitaxial deposition where deposition on dielectric surfaces must be reduced or prevented. A blocking layer can be employed to enable selective deposition, however, the blocking layer must be able to withstand deposition process conditions. Some epitaxial deposition processes call for relatively high temperatures, including temperatures ranging from 400 to 650 degrees Celsius. Therefore, there exists a need in the semiconductor industry for selective epitaxial process blocking chemistries that can be sustained at higher temperatures.

### SUMMARY

Implementations described herein generally relate to processes for the fabrication of semiconductor devices in which a blocking layer is selectively applied over a substrate, and the blocking layer used to direct selective epitaxial deposition. In one implementation, a method for selectively and epitaxially depositing a silicon-containing material layer on a substrate is provided. The method includes providing a substrate including an exposed dielectric material and an exposed silicon-based material, depositing a blocking layer on the exposed dielectric material, epitaxially and selectively depositing a silicon-containing material layer on the exposed silicon-based material, and removing the blocking layer from the exposed dielectric material.

In another implementation, a method for selectively and epitaxially depositing a silicon-containing material layer on a substrate is provided. The method includes exposing a substrate including an exposed dielectric material and an exposed silicon-based material to a pre-clean process, depositing a blocking layer on the exposed dielectric material, epitaxially and selectively depositing a silicon-containing material layer on the exposed silicon-based material, and removing the blocking layer from the exposed dielectric material.

In yet another implementation, a method for selectively and epitaxially depositing a silicon-containing material layer on a substrate is provided. The method includes exposing a substrate including an exposed dielectric material and an exposed silicon-based material to a plasma pre-clean process, depositing a blocking layer on the exposed dielectric material, wherein the blocking layer comprises a molecule of formula I:

X_{z}—Si—Y_{(4-z)}

wherein X is substituted or unsubstituted alkyl having 1 to 30 carbons atoms, substituted or unsubstituted aryl having 1 to 30 carbon atoms, or substituted or unsubstituted aralkyl having 1 to 30 carbon atoms, Y is halide, alkyl, or alkoxy, and z is an integer from 1 to 3. The method further includes epitaxially and selectively depositing a silicon-containing material layer on the exposed silicon-based material at a temperature of 400 degrees Celsius or greater, and removing the blocking layer from the exposed dielectric material.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIGS. 1A-1F depict cross-sectional schematic views of a workpiece processed according to implementations described herein.

FIG. 2 is a process flow diagram illustrating one method of selective deposition according to implementations described herein.

FIG. 3 includes exemplary blocking molecules according to implementations described herein.

FIG. 4 includes exemplary blocking molecules according to implementations described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

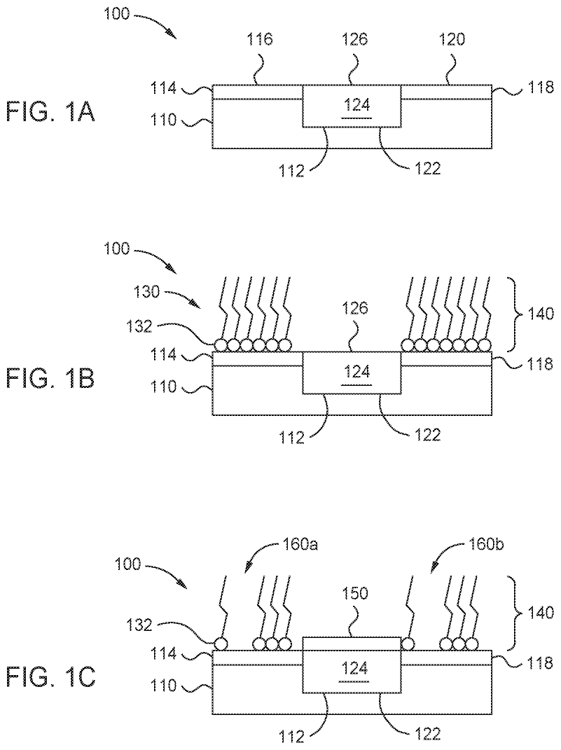

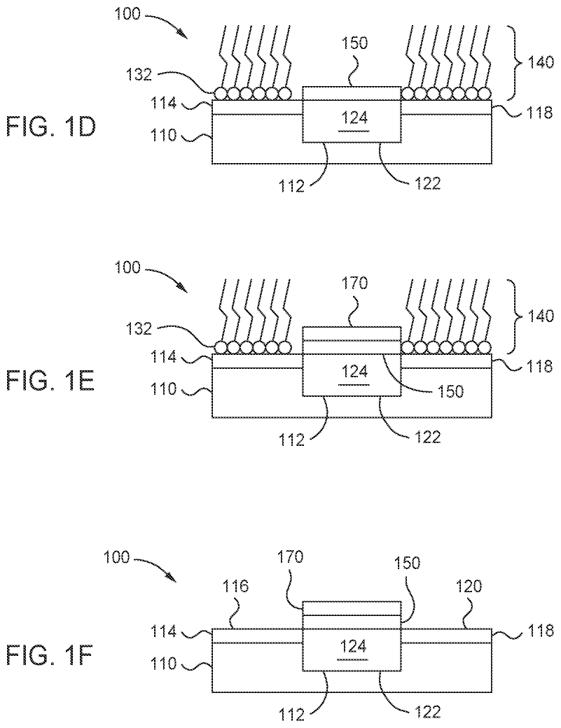

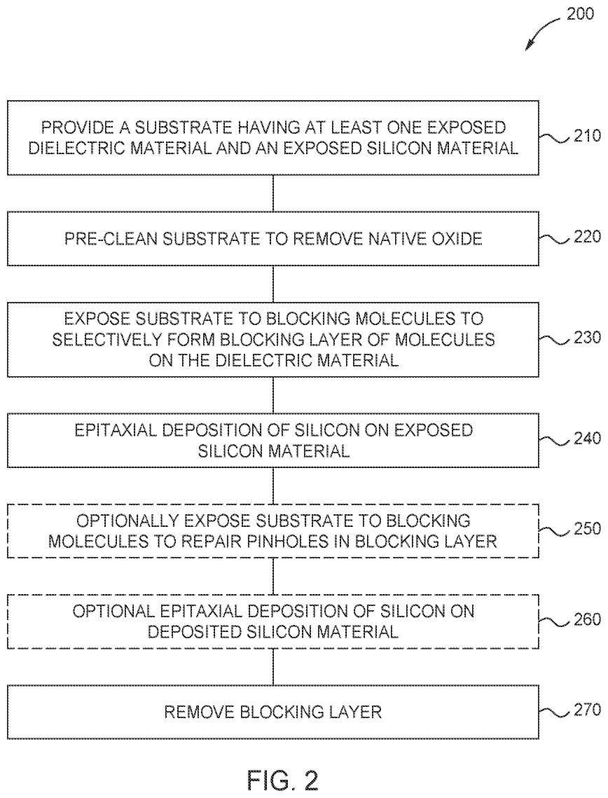

The following disclosure describes processes for the fabrication of semiconductor devices in which a self-assembled monolayer is used to achieve selective deposition at lower temperatures, including at ambient temperature. Certain details are set forth in the following description and in FIGS. 1A-1G and FIG. 2 to provide a thorough understanding of various implementations of the disclosure. Other details describing well-known structures and systems often associated with semiconductor devices, self-assembled monolayers, epitaxial deposition and surface preparation are not set forth in the following disclosure to avoid unnecessarily obscuring the description of the various implementations.

Many of the details, dimensions, angles and other features shown in the Figures are merely illustrative of particular implementations. Accordingly, other implementations can have other details, components, dimensions, angles and features without departing from the spirit or scope of the present disclosure. In addition, further implementations of the disclosure can be practiced without several of the details described below.

Implementations illustrated herein will be described below in reference to cleaning and deposition processes that can be carried out using systems available from Applied Materials, Inc. of Santa Clara, Calif. Other tools capable of performing these cleaning and deposition processes may be adapted to benefit from the implementations described herein. In addition, any system enabling the cleaning and deposition processes described herein can be used to advantage. The apparatus description described herein is illustrative and should not be construed or interpreted as limiting the scope of the implementations described herein.

Epitaxial silicon deposition processes are processes where crystalline silicon is deposited on a substrate's silicon seed layer. Some substrates are mixed-surface substrates that include both silicon surfaces and dielectric material surfaces. Upon exposure to epitaxial deposition conditions, silicon will be deposited upon both the silicon surface and the dielectric material surface.

Selective epitaxial silicon deposition processes are selective processes where crystalline silicon is selectively deposited on a silicon seed layer. Some selective epitaxial silicon deposition processes involve providing a layer of molecules over dielectric material surfaces in order to prevent or inhibit silicon deposition on the dielectric surface. These processes, however, are not amenable to higher-temperature silicon deposition because the molecules are not able to withstand temperatures of 400 degrees Celsius or greater. The present inventors have developed a method that enables selective epitaxial silicon deposition at temperatures of 400 degrees Celsius and greater. The method provides a means for performing selective epitaxial silicon deposition on mixed-surface substrates at temperatures ranging from 400 degrees Celsius to about 650 degrees Celsius. The method can involve deposition of blocking molecules in liquid phase or in vapor phase. The ability to deposit blocking molecules in the vapor phase allows the process to be scaled to larger substrates. In some embodiments, providing a blocking layer of blocking molecules on a substrate enables selective epitaxial silicon deposition at a temperature of any one of, less than, greater than, or between 400, 410, 420, 430, 440, 450, 460, 470, 480, 490, 500, 510, 520, 530, 540, 550, 560, 570, 580, 590, 600, 610, 620, 630, 640, and 650 degrees Celsius.

In some implementations of the present disclosure, epitaxial deposition of silicon on dielectric materials is inhibited or prevented by providing a blocking layer of molecules over the dielectric material. The blocking layer of molecules can withstand epitaxial deposition temperatures of 400 degrees Celsius and up to 650 degrees Celsius.

In some implementations of the present disclosure, blocking molecules are deposited on a substrate and the blocking molecules from a blocking layer on the substrate surface. In some embodiments, the substrate surface comprises SiO, SiOH, SiN, or a combination thereof. In some implementations, the blocking layer comprises a molecule of formula I:

X_{z}—Si—Y_{(1-z)}

wherein X is substituted or unsubstituted alkyl having 1 to 30 carbons atoms, substituted or unsubstituted aryl having 1 to 30 carbon atoms, or substituted or unsubstituted aralkyl having 1 to 30 carbon atoms, Y is halide, alkyl, or alkoxy, and z is an integer from 1 to 3. In some implementations, the substituted or unsubstituted alkyl optionally comprises at least one heteroatom selected from N, O, Si, and S within the alkyl group chain. In some embodiments, X can include one or more olefinic groups. In some implementations, the substituted or unsubstituted aralkyl group optionally comprises at least one heteroatom selected from N, O, Si, and S within the alkyl group chain. In some implementations, the substituted or unsubstituted aralkyl group optionally comprises at least one heteroatom selected from N, O, Si, and S within the aryl group ring. In some implementations, the substituted or unsubstituted aryl group optionally comprises at least one heteroatom selected from N, O, Si, and S within the aryl group ring. In some embodiments, a molecule of formula I comprises at least one halide or alkoxy group chemically-bonded to a silicon atom. In some embodiments, the at least one halide or alkoxy group acts as a leaving group and allows the molecule's silicon atom to bind to a functional group on the substrate surface. The blocking molecules can be deposited in either liquid phase or vapor phase under suitable process conditions. The liquid phase deposition can be performed using a suitable solvent for the blocking molecule. Non-limiting examples of suitable solvents include non-polar solvents, such as toluene and benzene, alcohols, such as ethanol, butanol, and isopropanol, ethers, such as tetrahydrofuran and diethyl ether, ketones, such as acetone, aprotic solvents, such as acetonitrile, and combinations thereof.

In some implementations of the present disclosure, a substrate is pre-cleaned prior to deposition of a blocking layer of blocking molecules on the substrate surface. In some implementations, which can be combined with other implementations, a substrate surface is pre-cleaned with hydrogen fluoride (HF). In some embodiments, the hydrogen fluoride is provided as a solution of hydrogen fluoride in water. A solution of hydrogen fluoride in water is also known as hydrofluoric acid. The aqueous hydrofluoric acid solution can have a concentration ranging from 0.5 weight % to 48 weight %. In some implementations, the hydrofluoric acid can have a concentration of from 1 weight % in water to 2 weight % in water.

In some embodiments, a substrate is pre-cleaned by contacting the substrate with hydrofluoric acid. In some embodiments, the substrate is pre-cleaned by contacting the substrate with a hydrofluoric acid solution for a period of time ranging from 5 seconds to 5 minutes, preferably ranging from 30 seconds to 2 minutes, more preferably ranging from 45 seconds to 90 seconds. In some embodiments, the substrate is pre-cleaned by contacting the substrate with a hydrofluoric acid solution for 60 seconds.

In some implementations, a substrate is pre-cleaned by dipping the substrate into hydrofluoric acid. The dipping time can vary depending upon the hydrofluoric acid concentration and the amount of SiOx, SiOH, or SiN present on the surface of the workpiece 100. In some embodiments, a 1% solution of hydrofluoric acid is used to pre-clean a substrate, wherein the 1% solution comprises 1 weight % of hydrogen fluoride in water. After pre-cleaning, the cleaned substrate can be dipped in a solution of a molecule of formula I in order to apply a blocking layer.

The phrase “blocking molecules” refers to molecules of formula I. A “blocking layer” generally refers to a layer of molecules of formula I that are attached to a substrate surface through a chemical bond. In some embodiments, the molecules in the blocking layer are arranged in a preferred orientation with respect to the substrate surface, and with respect to each other. The molecules of formula I comprise a “head group” and a “terminal end.” The head group includes at least one leaving group that is chemically bonded to a silicon atom. In some embodiments, the head group comprises at least one halide or an alkoxy group. Upon binding to the substrate surface, a functional group on the substrate surface binds to the silicon atom in the molecule of formula I and displaces a leaving group within the head group. Selection of the head group will depend on the substrate composition and epitaxial deposition conditions. The terminal end comprises a substituted or unsubstituted alkyl having 1 to 30 carbons atoms, a substituted or unsubstituted aryl having 1 to 30 carbon atoms, or a substituted or unsubstituted aralkyl having 1 to 30 carbon atoms. Non-limiting examples of alkyl groups that comprise at least one heteroatom within the alkyl group chain include —(CH₂)NHCH₃, —(CH₂)₂O(CH₂)₂CH₃, and —(CH₂)₃S(CH₂)₃CH₃. Non-limiting examples of aryl groups that comprise at least one heteroatom within the aryl group ring include a pyridyl group and a furyl group. Non-limiting examples of aralkyl groups that comprise at least one heteroatom within the aralkyl group ring include —(CH₂)-pyridine and —(CH₂)₂-furan. Non-limiting examples of aralkyl groups that comprise at least one heteroatom within the aryl group include —(CH₂)—O—(CH₂)₂-phenyl, —(CH₂)₂—SiMe((CH₂)₇)CH₃, and —(CH₂)₃—NH—(CH)₂-phenyl. Functional groups attached to the substituted alkyl, aryl, or aralkyl group can be selected to adjust blocking layer wetting or interfacial properties. In some embodiments, molecules of formula I will selectively bind to one material over another material (e.g., silicon vs. dielectric). In some embodiments, a layer of blocking molecules will successfully block deposition, allowing for selective deposition on materials not coated with a layer of blocking molecules.

“Alkyl” refers to and includes saturated linear, branched, or cyclic univalent hydrocarbon structures and combinations thereof. This term is exemplified by groups such as methyl, t-butyl, n-heptyl, octyl, cyclohexylmethyl, and cyclopropyl. Cycloalkyl is a subset of alkyl and can consist of one ring, such as cyclohexyl, or multiple rings, such as adamantyl. A cycloalkyl comprising more than one ring may be fused, spiro or bridged, or combinations thereof. Non-limiting examples of cycloalkyl groups include decahydronaphthalenyl, cyclopropyl, cyclobutyl, cyclopentyl, and cyclohexyl. “Substituted alkyl” refers to an alkyl group having at least one substituent bonded to an alkyl group carbon atom.

“Aryl” refers to an unsaturated, aromatic carbocyclic group having at least one ring. Non-limiting examples of aryl groups include phenyl, naphthyl, and anthryl. “Substituted aryl” refers to an aryl group having at least one substituent bonded to an aryl group carbon atom.

“Aralkyl” refers to a moiety in which an aryl group is attached to an alkyl group and wherein the aralkyl moiety may be attached to the silicon atom at either the aryl group or the alkyl group. A “substituted aralkyl” refers to an aralkyl moiety having at least one substituent bonded to a carbon atom within the aralkyl moiety.

Non-limiting examples of substituents include alkoxy, substituted alkoxy, acyl, acyloxy, carbonylalkoxy, acylamino, substituted or unsubstituted amino, aminoacyl, aminocarbonylamino, aminocarbonyloxy, aryl, substituted aryl, heteroaryl, substituted heteroaryl, aryloxy, substituted aryloxy, cyano, halide, hydroxyl, nitro, carboxyl, thiol, thioalkyl, substituted or unsubstituted silyl, substituted or unsubstituted alkenyl, substituted or unsubstituted alkynyl, substituted or unsubstituted heterocyclyl, substituted or unsubstituted aralkyl, aminosulfonyl, sulfonylamino, sulfonyl, oxo, carbonylalkylenealkoxy, and the like.

“Alkoxy” refers to the group —O-alkyl, which includes, by way of example, methoxy, ethoxy, n-propoxy, iso-propoxy, n-butoxy, tert-butoxy, sec-butoxy, n-pentoxy, n-hexoxy, 1,2-dimethylbutoxy, and the like. “Halide” refers to elements of the Group 17, including fluoride, chloride, bromide, and iodide.

Referring to FIGS. 1A-1F, a substrate 110 having at least an exposed first material and an exposed second material is provided. In one implementation, the substrate 110 can comprise a silicon-based material, which can include crystalline silicon, silicon oxide, strained silicon, silicon germanium, doped or undoped polysilicon, doped or undoped silicon wafers, patterned or non-patterned wafers, silicon on insulator (SOI), carbon doped silicon oxides, silicon nitride, doped silicon, germanium, gallium arsenide, glass, sapphire, and combinations thereof. The substrate 110 can have various dimensions, such as 200 mm, 300 mm, 450 mm or other diameter, as well as, being a rectangular or square panel. In the implementation depicted herein, the substrate 110 may be a crystalline silicon substrate. Moreover, the substrate 110 is not limited to any particular size or shape. The substrate 110 may be a round substrate having a 200 mm diameter, a 300 mm diameter or other diameters, such as 450 mm, among others. The substrate 110 may also be any polygonal, square, rectangular, curved or otherwise non-circular workpiece, such as a polygonal glass substrate used in the fabrication of flat panel displays.

The substrate 110 may include a feature 112. The feature 112 may include, for example, trenches, vias, holes, openings, lines, the like, and combinations thereof. A first material layer 114 (e.g., a dielectric material) having an exposed surface 116 is formed on a surface of the substrate 110. A second material layer 118 (e.g., a dielectric material) having an exposed surface 120 is also formed on the surface of the substrate 110. In one implementation, the feature 112 has an opening 122 that is filled with a third material 124 (e.g., a silicon-based material) having an exposed surface 126 disposed on the substrate 110 as shown in FIG. 1A. It should be understood that the first material layer 114 and the second material layer 118 may both be dielectric materials. In some implementations, the first material layer 114 is a silicon oxide layer and the second material layer 118 is a silicon nitride layer. In some implementations, the first material layer 114 and the second material layer are formed from the same dielectric material (e.g., both silicon nitride or silicon oxide). In some implementations, the feature 112 is not present and the exposed surface 126 is the surface of the substrate 110.

An exemplary blocking layer deposition process can involve a pre-clean process prior to blocking layer deposition. The pre-clean process may be any pre-clean process capable of removing native oxides, contaminants, or both from the exposed surfaces. The pre-clean process may be a dry chemical clean process, a wet chemical clean process, or both. The pre-clean process may be a remote plasma clean or an in-situ plasma clean that is adapted to perform a dry etch process. One exemplary dry cleaning process is the SICONI™ Pre-clean process available from Applied Materials, Inc., which removes native oxide through a low-temperature, two-part dry chemical clean process using NF₃ and NH₃. The pre-clean process may be an ex-situ pre-clean process or an in-situ pre-clean process (e.g., without exposure to atmosphere in between cleaning and additional processing of the substrate).

In one implementation, a pre-clean process includes exposing the workpiece 100 to an ex-situ organic wet clean. In one implementation, the ex-situ organic wet clean process is a sonication process in the presence of an organic liquid. In one implementation, the ex-situ organic wet clean includes at least one of sonication in acetone, sonication in isopropanol (IPA), and sonication in water. In one implementation, the ex-situ organic wet clean includes a ten-minute sonication in acetone, followed by a ten-minute sonication in IPA, followed by a ten-minute sonication in water.

In one implementation, a pre-clean process includes exposing the workpiece 100 to a hydrofluoric acid (HF) solution. The hydrofluoric acid solution may be in liquid or vapor phase. The hydrofluoric acid solution may be a dilute hydrofluoric (DHF) acid solution. The hydrofluoric acid may be buffered hydrofluoric acid (BHF) or non-buffered. An exemplary buffering agent for buffering HF is ammonium fluoride (NH₄F). The hydrofluoric acid solution may be chosen because it is believed that the hydrofluoric acid solution will remove native oxides from the surface of the workpiece 100. Factors such as the concentration of the dilute hydrofluoric acid solution and the time-period of exposure of the workpiece 100 to the dilute HF will affect the amount of native oxides removed from the surface of the workpiece 100.

The workpiece 100 can be dipped in the dilute acid solution for a period of, for example, about 30 seconds to about 800 seconds. In some implementations, the dilute acid solution may be sprayed onto the workpiece 100. Optionally, following exposure of the workpiece 100 to the hydrofluoric acid solution, a post-exposure rinse process using, for example, DI water, may be used to clean the substrate surface. The optional clean process may be followed by an optional drying process using drying methods known in the art.

In one implementation, the workpiece 100 undergoes an ex-situ wet organic clean with a ten minute sonication in acetone, followed by ten minute sonication in IPA, followed by ten minute sonication in water. The workpiece 100 is then dipped into a beaker, which contains a 2% HF/water solution with a layer of toluene on top for 1 minute. After 1 minute, the sample is pulled out through the layer of toluene and quickly transferred into an octadecyltrichlorosilane (ODTS) solution before the layer of toluene evaporates from the surface of the workpiece 100.

As depicted in FIG. 1B, a method of forming a blocking layer on a substrate 110 involves exposing the substrate 110 to molecules of formula I to achieve selective binding of the molecules of formula I on the exposed surface 116 of the first material layer 114 and the exposed surface 120 of the second material layer 118 with minimal to no binding to the exposed surface 126 of the third material 124. Depending upon the materials used and the molecules used, the molecule of formula I can be provided in liquid or gaseous form. The substrate 110 can be exposed to molecules of formula I in a gas-phase process (e.g., a chemical vapor deposition (CVD) process) or a liquid-phase process (e.g., a dip-coating process) where the substrate 110 is dipped into a solution containing molecules of formula I. The substrate 110 can be exposed to molecules of formula I 130, precursors that form the molecules of formula I 130, or both. The molecules of formula I bind to the exposed surface 116 of the first material layer 114 and the exposed surface 120 of the second material layer 118 to form a blocking layer 140.

The blocking layer 140 comprises an organized layer of molecules of formula I 130 in which the head group 132 shows a selective and reversible affinity for the first material layer 114 and the second material layer 118 of the feature 112. The head group 132 can include halide or alkoxy leaving groups bound to a silicon atom. The silicon atom can be bound to a tail group that comprises a substituted or unsubstituted alkyl group, a substituted or unsubstituted aralkyl group, or a substituted or unsubstituted aryl group. The blocking layer 140 is formed by covalent binding of the head group 132 onto the first material layer 114 and the second material layer 118 of the feature 112, followed by two-dimensional organization of the hydrophobic tail groups. Covalent binding between blocking molecules and substrate can occur in liquid phase by immersion of the substrate 110 into a solution containing the blocking molecules. In one implementation, the blocking layer 140 is deposited via spin-coating from a solution. Covalent binding between blocking molecules and substrate can also occur from vapor-phase deposition by exposing the substrate 110 to gaseous blocking molecules or blocking molecule precursors. The blocking molecules initially form a disordered mass of molecules and then begin to form crystalline or semi-crystalline structures on the first material layer 114 and the second material layer 118 of the workpiece 100. The thickness of the blocking layer 140 can be adjusted by adjusting the length of the blocking molecules 130. For example, a layer of blocking molecules that are 20 atoms in length will provide a layer that is thicker than a layer of blocking molecules that are 10 atoms in length. Generally, the blocking layer 140 selectively forms on surfaces that are capable of chemically reacting with and covalently binding to molecules of formula I 130.

As depicted in FIG. 1B, the blocking molecules 130 utilized to form the blocking layer 140 are selected to selectively react with the exposed surface 116 of the first material layer 114, (e.g., a silicon oxide material) and the exposed surface 120 of the second material layer 118, rather than the exposed surface 126 of the third material 124 (e.g., a silicon-based material). By doing so, the blocking layer 140 is preferentially formed on the exposed surface 116 of the first material layer 114 and the exposed surface 120 of the second material, leaving the exposed surface 126 of the third material 124 free of the blocking layer 140.

In one implementation, the blocking layer 140 is formed at a pressure from about 50 millitorr to about 10 Torr (e.g., from about 50 mTorr to 1 Torr; from about 50 millitorr to about 500 millitorr; from about 1 Torr to about 10 Torr; or from about 5 Torr to about 10 Torr). In one implementation, the blocking layer 140 is formed for a time period between about 50 milliseconds to about 10 minutes (e.g., from about 50 milliseconds to about 200 milliseconds; from about 50 milliseconds to about 100 milliseconds; from about 1 minute to about 5 minutes; or from about 5 minutes to about 10 minutes).

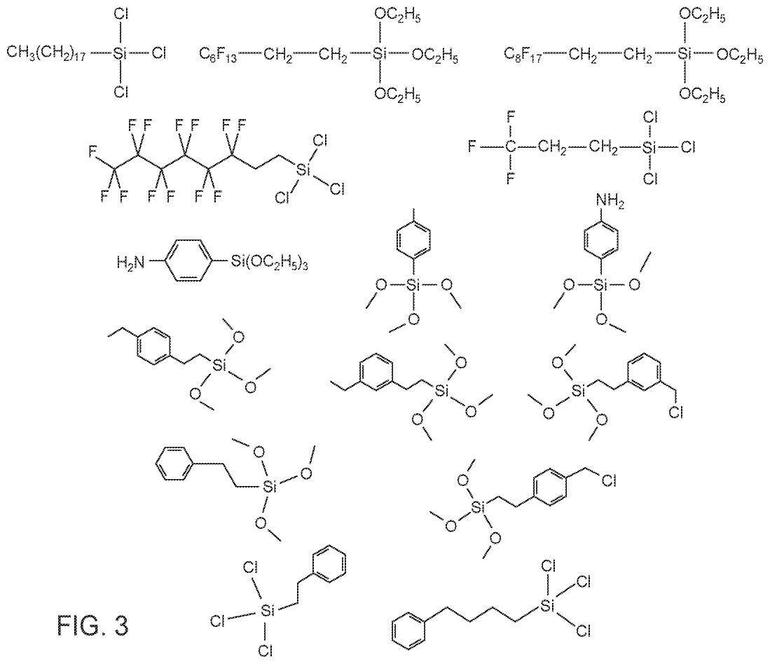

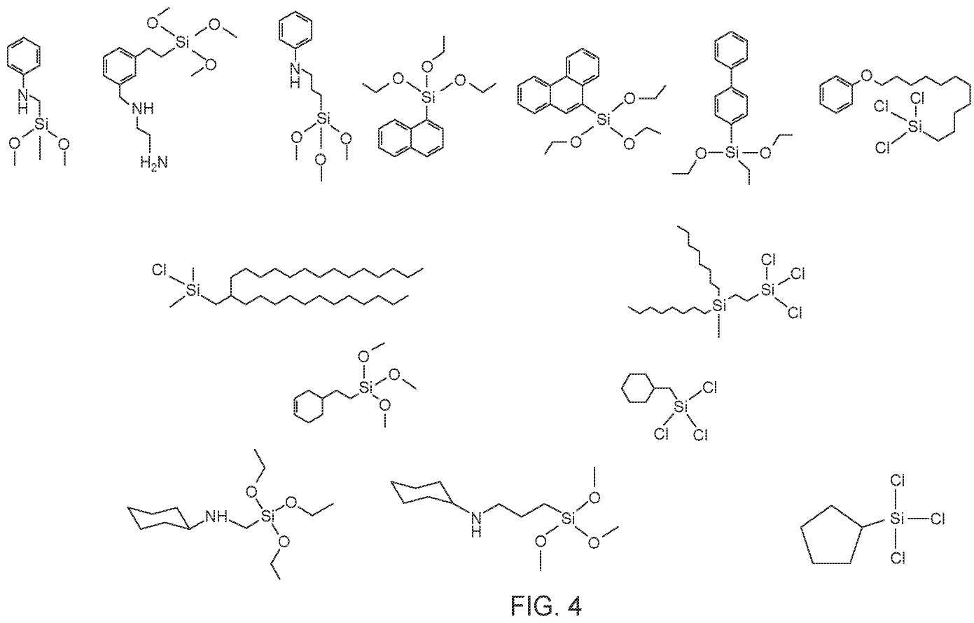

In another implementation, the molecules of formula I 130 can be chlorosilane molecules, such as methyltrichlorosilane, ethyltrichlorosilane, propyltrichlorosilane, butyltrichlorosilane, pentyltrichlorosilane, hexyltrichlorosilane, heptyltrichlorosilane, octyltrichlorosilane, nonyltrichlorosilane, decyltrichlorosilane, undecyltrichlorosilane, dodecyltrichlorosilane, tridecyltrichlorosilane, tetradecyltrichlorosilane, pentadecyltrichlorosilane, hexadecyltrichlorosilane, heptadecyltrichlorosilane, octadecyltrichlorosilane (ODTS), 2-(3-cyclohexenyl) ethyltrimethoxysilane, nonadecyltrichlorosilane, (cyclohexylmethyl)trichlorosilane, 2-(di-n-octylmethylsilyl) ethyltrichlorosilane, 13-(chlorodimethylsilylmethyl) heptacosane, N-cyclohexyl(aminomethyl) triethoxysilane, N-cyclohexyl(aminopropyl) trimethoxysilane, trichlorocyclopentylsilane, and combinations thereof. Additionally, non-limiting examples of molecules of formula I are depicted in FIG. 3 and FIG. 4.

As depicted in FIG. 1C, a low temperature deposition process, which is a process highly sensitive to surface conditions having selected precursors, is then performed to form a structure 150 selectively on the exposed surface 126 of the third material 124. In one implementation, the structure 150 is formed from a silicon-containing material. In one implementation, the structure 150 is formed from polycrystalline silicon.

The structure 150 can be formed by various deposition techniques including, for example, CVD such as plasma-enhanced CVD (PE-CVD), pulsed-CVD, low pressure CVD (LPCVD), epitaxial growth, atomic layer deposition (ALD), hot-wire CVD (HWCVD), hydride vapor phase epitaxial (HVPE) processes, atomic layer deposition (ALD) processes, Atomic Layer Epitaxy (ALE) and/or any other suitable process. In one implementation, the deposition process is a CVD process, for example, a Hot-Wire CVD (HWCVD) process. The deposition process can be a high temperature deposition process. The high temperature deposition process is typically performed at a temperature ranging from 400 degrees Celsius to 650 degrees Celsius. The material selected to be deposited can be influenced by the surface properties of the substrate. The thickness of the structure 150 will vary depending on the materials and particular device being formed. The blocking layer 140 prevents deposition of the material of the structure 150 on the exposed surface 116 of the first material layer 114 and the exposed surface 120 of the second material layer 118. In this manner, a selective deposition process may selectively deposit different materials at different locations on the substrate.

In one implementation, the silicon-containing material is formed from a processing gas. The processing gas can include at least one of a silicon-containing precursor gas, a boron-containing precursor gas, a hydrogen-based precursor gas, and inert gases. Exemplary silicon-containing precursor gases for forming the structure 150 include silane-containing precursor gases, including, but not limited to silane (SiH₄), disilane (Si₂H₆), higher order silanes, and the like. Exemplary boron-based precursor gases for forming the structure 150 include, but are not limited to, trimethylboron ((B(CH₃)₃) or TMB), diborane (B₂H₆), boron trifluoride (BF₃), and triethylboron ((B(C₂H₅)₃) or TEB) and combinations thereof. Suitable hydrogen-based precursor gases include, but are not limited to, H₂, H₂O, H₂O₂ and combinations thereof.

In one implementation, the silicon-containing material deposition process is an ALD process. As the ALD process is sensitive to surface conditions, ALD is suitable for a selective deposition of materials on specific regions of the substrate. The ALD process is a CVD process with self-terminating/limiting growth. The ALD process yields a thickness of only a few angstroms or in a monolayer level. The ALD process is controlled by distribution of a chemical reaction into two separate half reactions, which are repeated in cycles. The thickness of the material formed by the ALD process depends on the number of the reaction cycles. The first reaction provides a first atomic layer of molecular layer being absorbed on the substrate and the second reaction provides a second atomic layer of molecular layer being absorbed on the first atomic layer. As such, the ordered structure of the material acts as a template for the growth of the material layer.

As shown in FIG. 1C, in some implementations, after deposition of the structure 150, the blocking layer 140 may be damaged. This damage may take the form of holes or pinholes 160a, 160b (collectively 160) that expose portions of at least one of the exposed surface 116 and the exposed surface 120. During subsequent deposition processes, these exposed or unprotected portions may have materials deposited thereon. Thus, in some implementations, the substrate 110 is exposed to a repair process.

As depicted in FIG. 1D, the workpiece 100 may be exposed to a blocking layer repair process to repair damage to the blocking layer 140 that occurs during the epitaxial deposition process depicted in FIG. 1C. This damage may include pinholes present in the blocking layer 140 after formation of the structure 150. The repair process depicted in FIG. 1D may include repeating the blocking layer formation process. In one implementation, the repair process of FIG. 1D can include at least one of the following: chemical treatment of the blocking layer to block pinholes via steric hindrance, plasma treatment of the blocking layer to form a successive layer on the blocking layer, exposing the blocking layer to a chemical precursor to form a successive layer on the blocking layer, or combinations thereof. In one implementation, repair of the pinholes can include repeating the process depicted in FIG. 1B.

In one implementation, the repair process depicted in FIG. 1D includes exposing the deposited blocking layer 140 to a plasma treatment process. Not to be bound by theory but it is believed that the plasma treatment process densifies the deposited blocking layer 140 and reduces the number of pinholes formed during the deposition process depicted in FIG. 1C. Depending on the type of deposition and plasma pinhole reduction techniques used, one or more of the power sources connected to the substrate can be a DC source, a pulsed DC (pDC) source, an RF source, a pulsed RF source, etc. Similarly, one or more of the target power sources can be a DC source, a pDC source, an RF source, a pulsed RF source, etc. A post-deposition treatment can involve inducing and maintaining a plasma over the workpiece 100 to provide ion bombardment of the deposited blocking layer 140. This type of post-deposition treatment can restructure the surface morphology of the blocking layer 140 and/or modify the composition of the blocking layer 140 itself.

In one implementation, the blocking layer 140 is densified by exposing the workpiece 100 to an RF plasma. In this type of process, essentially no additional material is deposited on the blocking layer 140, rather, the impact of the accelerated ionic species densifies the blocking layer 140.

Referring to FIG. 1E, the deposition process of FIG. 1B may be repeated to selectively deposit additional material 170 on the structure 150.

Referring to FIG. 1F, following the deposition processes of 1C, 1D, and 1E, the blocking layer 140 is removed from the exposed surface 116 of the first material layer 114 and the exposed surface 120 of the second material layer 118. The blocking layer 140 may be removed by any process which does not adversely affect the structure 150 or the exposed surface 116 and the exposed surface 120. The process for removing the blocking layer 140 depends on the selection of the blocking molecules. The blocking layer 140 can be removed by a wet etching process, a dry etching process, or a high temperature anneal process (e.g., equal to or greater than 400 degrees Celsius) to release the blocking layer 140 from the exposed surface 116 of the first material layer 114 and the exposed surface 120 of the second material layer 118.

FIG. 2 is a flow chart depicting a process flow diagram illustrating one method 200 of a selective deposition process performed with a blocking layer of molecules according to implementations described herein. The method 200 may be used to form a structure as depicted in the sequence of fabrication stages depicted in FIGS. 1A-1F, which are discussed above. At operation 210, a workpiece substrate comprising at least one exposed dielectric material and an exposed silicon-based material is provided. At operation 220, the substrate is pre-cleaned to remove native oxide moieties on the substrate surface. At operation 230, the substrate is exposed to blocking molecules to selective form a blocking layer of molecules on the dielectric material. At operation 240, silicon is epitaxially deposited on the exposed silicon-based material. At optional operation 250, the substrate can be exposed to blocking molecules to repair pinholes in the blocking layer of molecules. At optional operation 260, a subsequent layer of silicon can be epitaxially deposited on exposed silicon-based material. At operation 270, the blocking layer of molecules is removed from the workpiece.

In summary, some benefits of some implementations of the present disclosure provide methods for achieving selective epitaxial deposition at temperatures ranging from 400 degrees Celsius to 650 degrees Celsius. This ability to perform epitaxial deposition at higher temperatures improves the available temperature-processing window allowing for fabrication of multiple devices. In some implementations, this selective epitaxial deposition is achieved via use of a blocking material, which deposits on dielectric materials (e.g., silicon oxide, silicon nitride, and silicon oxynitride) while leaving silicon-based material surfaces exposed. The blocking material may be deposited in the same chamber as the subsequently deposited epitaxial layer, which reduces the formation of unwanted oxides on the exposed silicon-based material.

When introducing elements of the present disclosure or exemplary aspects or implementation(s) thereof, the articles “a,” “an,” “the” and “said” are intended to mean that there are one or more of the elements.

The terms “comprising,” “including” and “having” are intended to be inclusive and mean that there may be additional elements other than the listed elements.

While the foregoing is directed to implementations of the present disclosure, other and further implementations of the present disclosure may be devised without departing from the basic scope thereof, and the scope thereof is determined by the claims that follow.

What is claimed is:

1. A method for selectively and epitaxially depositing a silicon-containing material layer on a substrate, comprising:
providing a substrate comprising an exposed dielectric material and an exposed silicon-based material;
depositing a blocking layer on the exposed dielectric material;
epitaxially and selectively depositing a silicon-containing material layer on the exposed silicon-based material; and
removing the blocking layer from the exposed dielectric material.

2. The method of claim 1, further comprising cleaning the substrate prior to deposition of the blocking layer.

3. The method of claim 2, wherein cleaning the substrate comprises treating the substrate with hydrofluoric acid.

4. The method of claim 1, wherein the blocking layer comprises a molecule of formula I:
X_{z}—Si—Y_{(1-z)} (I)
wherein:
X is substituted or unsubstituted alkyl having 1 to 30 carbons atoms, substituted or unsubstituted aryl having 1 to 30 carbon atoms, or substituted or unsubstituted aralkyl having 1 to 30 carbon atoms;
Y is halide, alkyl, or alkoxy; and
z is an integer from 1 to 3.

5. The method of claim 4, wherein depositing a blocking layer on the exposed dielectric material comprises exposing the substrate to a solution comprising molecules of formula I.

6. The method of claim 4, wherein depositing a blocking layer on the exposed dielectric material comprises exposing the substrate to a gas comprising molecules of formula I.

7. The method of claim 1, wherein the blocking layer has one or more pinholes formed therein after epitaxially and selectively depositing the silicon-containing material layer on the exposed silicon-based material.

8. The method of claim 7, further comprising exposing the substrate to a gas or solution comprising molecules of formula I to repair the one or more pinholes.

9. The method of claim 1, wherein epitaxial deposition is performed at a temperature ranging from 400 degrees Celsius to 650 degrees Celsius.

10. A method for selectively and epitaxially depositing a silicon-containing material layer on a substrate, comprising:
exposing a substrate comprising an exposed dielectric material and an exposed silicon-based material to a pre-clean process;
depositing a blocking layer on the exposed dielectric material;
epitaxially and selectively depositing a silicon-containing material layer on the exposed silicon-based material; and
removing the blocking layer from the exposed dielectric material.

11. The method of claim 10, wherein cleaning the substrate comprises treating the substrate with hydrofluoric acid.

12. The method of claim 1, wherein the blocking layer comprises a molecule of formula I:
X_{z}—Si—Y_{(1-z)}
wherein:
X is substituted or unsubstituted alkyl having 1 to 30 carbons atoms, substituted or unsubstituted aryl having 1 to 30 carbon atoms, or substituted or unsubstituted aralkyl having 1 to 30 carbon atoms;
Y is halide, alkyl, or alkoxy; and
z is an integer from 1 to 3.

13. The method of claim 12, wherein depositing a blocking layer on the exposed dielectric material comprises exposing the substrate to a solution comprising molecules of formula I.

14. The method of claim 12, wherein depositing a blocking layer on the exposed dielectric material comprises exposing the substrate to a gas comprising molecules of formula I.

15. A method for selectively and epitaxially depositing a silicon-containing material layer on a substrate, comprising:
exposing a substrate comprising an exposed dielectric material and an exposed silicon-based material to a plasma pre-clean process;
depositing a blocking layer on the exposed dielectric material, wherein the blocking layer comprises a molecule of formula I:
X_{z}—Si—Y_{(1-z)}
X is substituted or unsubstituted alkyl having 1 to 30 carbons atoms, substituted or unsubstituted aryl having 1 to 30 carbon atoms, or substituted or unsubstituted aralkyl having 1 to 30 carbon atoms;
Y is halide, alkyl, or alkoxy; and
z is an integer from 1 to 3;
epitaxially and selectively depositing a silicon-containing material layer on the exposed silicon-based material at a temperature of 400 degrees Celsius or greater; and
removing the blocking layer from the exposed dielectric material.

16. The method of claim 15, wherein depositing a blocking layer on the exposed dielectric material comprises exposing the substrate to a solution comprising molecules of formula I.

17. The method of claim 15, wherein depositing a blocking layer on the exposed dielectric material comprises exposing the substrate to a gas comprising molecules of formula I.

18. The method of claim 15, wherein epitaxial deposition is performed at a temperature ranging from 400 degrees Celsius to 650 degrees Celsius.

19. The method of claim 15, wherein the blocking layer has one or more pinholes formed therein after epitaxially and selectively depositing the silicon-containing material layer on the exposed silicon-based material.

20. The method of claim 19, further comprising exposing the substrate to a gas or solution comprising molecules of formula I to repair the one or more pinholes.
